(19) United States
(12) Patent Application Publication
(10) Pub. No.: US 2012/0327569 A1
(43) Pub. Date: Dec. 27, 2012

(54) TOUCH PANEL

(75) Inventors: Ho Joon Park, Seoul (KR); Ji Soo Lee, Gyunggi-do (KR)

(73) Assignee: SAMSUNG ELECTRO-MECHANICS CO., LTD., Gyunggi-do (KR)

(21) Appl. No.: 13/232,375

(22) Filed: Sep. 14, 2011

(30) Foreign Application Priority Data
Jun. 27, 2011 (KR) 1020110062418

(51) Int. Cl. H05K 7/00; H05K 13/00

(52) U.S. Cl. 361/679.01; 29/592.1

(57) ABSTRACT

Disclosed herein is a touch panel, including: a base member; a transparent electrode formed on the base member in a mesh shape including a plurality of openings surrounded by a line patterned with metal; and electrode wirings integrally formed on one end or both ends of the transparent. The preferred embodiment of the present invention integrally forms the electrode wirings with the transparent electrode made of metal, thereby simplifying the process and reducing the manufacturing process time. In addition, the preferred embodiment of the present invention forms the transparent electrode in the mesh shape to increase an aperture ratio, thereby increasing transmittance of the touch panel and electric conductivity of the transparent electrode.

### CROSS REFERENCE TO RELATED APPLICATION

This application claims the benefit of Korean Patent Application No. 10-2011-0062418, filed on Jun. 27, 2011, entitled “Touch Panel”, which is hereby incorporated by reference in its entirety into this application.

### BACKGROUND OF THE INVENTION

1. Technical Field

The present invention relates to a touch panel.

2. Description of the Related Art

As a computer using a digital technology is developed, accessory devices of the computer have been developed. A personal computer, a portable transmission device, and other personal only information processing device, or the like, perform text and graphic processing using various input devices such as a keyboard, a mouse, or the like.

However, as an information-oriented society is rapidly progressed, the use of the computer is more and more expanded. It is difficult to efficiently drive products only by the keyboard and the mouse serving as the current input device. Therefore, a need for device that is simple and has minimal malfunction while anyone can easily input information has increased.

In addition, a technology for an input device has been evolved to a technology having high reliability, durability, innovation, and design and machining, including a technology of satisfying a general function. In order to achieve the above objects, a touch panel as an input device capable of inputting information such as text, graphic, or the like, has been developed.

The touch panel is installed on a flat panel display such as a liquid crystal display device (LCD), a plasma display panel (PDP), electroluminescence (El), or the like, and a display surface of an image display device such as a cathode ray tube (CRT), which is a tool used for a user to select desired information while watching an image display device.

The types of touch panels are classified into a resistive type, a capacitive type, an electro-magnetic type, a surface acoustic wave type (SAW type), and an infrared type. Various types of touch panels are used for electronics in consideration of a problem of signal amplification, a difference in resolution, a difficulty in a design and machining technology, optical characteristics, electrical characteristics, mechanical characteristics, environmental characteristics, input characteristics, durability, and an economic value. The type most widely used for various fields is the resistive touch panel and the capacitive touch panel.

The resistive touch panel has a structure in which upper/lower transparent electrode layers are spaced apart from each other by a spacer and are disposed to contact each other by pressing. When the upper touch panel on which the upper transparent electrode layer is pressed by input units such as fingers, pen, or the like, there are a digital resistive type and an analog resistive type in which the upper/lower transparent electrode layers are conducted to each other and contact coordinates are recognized by allowing a control unit to recognize a change in voltage according to a change in a resistance value at the position.

The capacitive touch panel has a structure in which an upper substrate on which a first transparent electrode is formed and a lower substrate on which a second transparent electrode is formed are spaced apart from each other and an insulating material is inserted therebetween so as to prevent the first transparent electrode and the second transparent from being contacted with each other. In addition, the upper substrate and the lower substrate are provided with electrode wirings connected with the transparent electrode. The electrode wirings transfers the change in capacitance generated from the first transparent electrode and the second transparent electrode due to the contact of the input unit and the touch screen to the control unit.

Meanwhile, in the prior art, the transparent electrode is made of indium tin oxide (ITO) or a conductive polymer such as polyethylene dioxythiophene/polystyrene sulfonate (PEDOT/PSS). The ITO has excellent electric conductivity but is very expensive due to indium that is a rare earth metal as a raw material. As a result, the indium is expected to be depleted within the next decade and the supply and demand thereof is not smooth. The conductive polymer is a material emerged as a material replacing the ITO, which has excellent flexibility and easy machining capability but has degraded electric conductivity.

Therefore, a study to form the transparent electrode using a metal that has excellent electric conductivity and is smooth in view of supply and demand as compared with the ITO or the conductive polymer has been progressed.

### SUMMARY OF THE INVENTION

The present invention has been made in an effort to provide a touch panel including a transparent electrode made of a metal capable of reducing manufacturing process time while having excellent transmittance and electric conductivity and a method for manufacturing the same.

According to a preferred embodiment of the present invention, there is provided a touch panel, including: a base member; a transparent electrode formed on the base member in a mesh shape including a plurality of openings surrounded by a line patterned with metal; and electrode wirings integrally formed on one end or both ends of the transparent electrode.

The metal may be copper (Cu), aluminum (Al), gold (Au), or silver (Ag).

A width of the line patterned with the metal of the transparent electrode may be 1 μm to 10 μm.

A thickness of the line patterned with the metal of the transparent electrode may be 0.0 μm to 2 μm.

Sheet resistance of the transparent electrode may be 150 Ω/□ or less.

Transmittance of the touch panel may be 88% or more.

A surface of the transparent electrode may be subjected to a black oxide treatment.

According to a preferred embodiment of the present invention, there is provided a method for manufacturing a touch panel, including: (A) providing a base member; and (B) integrally forming a transparent electrode in a mesh shape including a plurality of openings and electrode wirings connected to one end or both ends of the transparent electrode on the base member by metal patterning.

The metal may be copper (Cu), aluminum (Al), gold (Au), or silver (Ag).

A width of the line patterned with the metal of the transparent electrode may be 1 μm to 10 μm.

A thickness of the line patterned with the metal of the transparent electrode may be 0.01 μm to 2 μm.

Sheet resistance of the transparent electrode may be 150 Ω/□ or less.

Transmittance of the touch panel may be 88% or more.

The method for manufacturing a touch panel may further include performing a black oxide treatment on a surface of the transparent electrode after step (B).

### BRIEF DESCRIPTION OF THE DRAWINGS

FIG. 1 is a plan view of a touch panel according to a preferred embodiment of the present invention.

FIG. 2A is an enlarged view of portion A of FIG. 1.

FIGS. 2B and 2C are enlarged views showing a modified example of a mesh shape.

FIG. 3 is a cross-sectional view of the touch panel according to the preferred embodiment of the present invention.

FIG. 4 is an enlarged view of portion B of FIG. 1.

FIGS. 5 and 6 are plan views showing a process for manufacturing a touch panel according to the preferred embodiment of the present invention.

### DESCRIPTION OF THE PREFERRED EMBODIMENTS

The features and advantages of the present invention will be more obvious from the following description with reference to the accompanying drawings.

Terms or words used in the specification and claims herein should be not construed as a general and lexical meaning and should be construed as the meaning and concept meeting the technical idea of the present invention based on a principle that the present inventors can properly define the concepts of terms in order to elucidate their own invention in the best method.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In describing the present invention, a detailed description of related known functions or configurations will be omitted so as not to obscure the gist of the present invention.

Hereinafter, exemplary embodiments of the present invention will be described in detail with reference to the accompanying drawings.

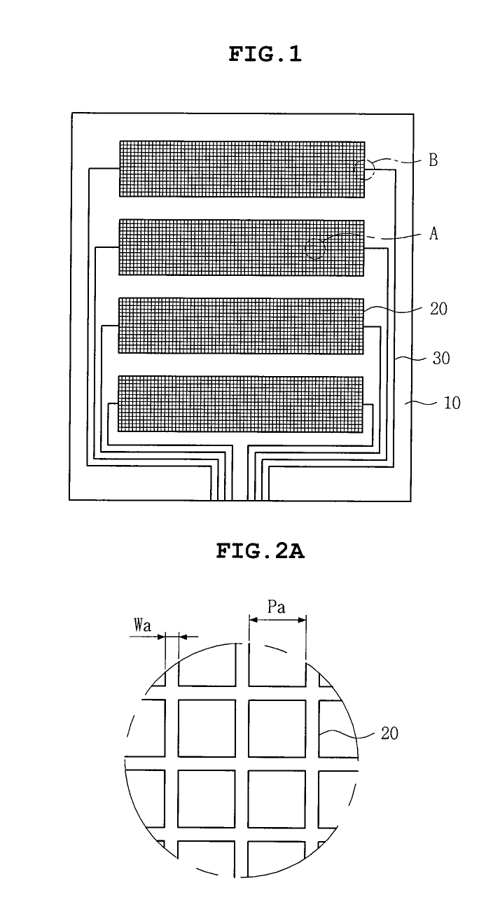

As shown in FIG. 1, a touch panel according to a preferred embodiment of the present invention includes a base member 10, a transparent electrode 20 formed on the base member 10 in a mesh shape including a plurality of openings surrounded by a line patterned with metal, and electrode wirings 30 integrally formed on one end or both ends of the transparent electrode 20. The preferred embodiment of the present invention may simplify the manufacturing process and reduce the manufacturing process time by integrally forming the electrode wirings 30 with the transparent electrode 20 made of metal. Hereinafter, components of the preferred embodiment of the present invention will be individually described in detail.

First, the base member 10 of the preferred embodiment of the present invention is made of a material having a support force supporting the transparent electrode 20 and transparency allowing a user to recognize images displayed on a display. The base member 10 may be made of polyethylene terephthalate (PET), polycarbonate (PC), poly methyl methacrylate (PMMA), polyethylene terephthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, or tempered glass, but is not necessarily thereto.

Next, the transparent electrode 20 made of metal according to the preferred embodiment of the present invention is formed on the base member 10. The transparent electrode 20 is a component sensing a change in capacitance (capacitive type) or a change in a resistance value (resistive type) when a user's hand touches a touch screen. As a metal material forming the transparent electrode 20, copper (Cu), aluminum (Al), gold (Au), silver (Ag), titanium (Ti), palladium (Pd), chromium (Cr), or a combination thereof may be used. The transparent electrode 20 may be made of copper (Cu), aluminum (Al), gold (Au), or silver (Ag), all of which have excellent electric conductivity. However, the preferred embodiment of the present invention is not limited thereto. As a result, all the metals, which have excellent electric conductivity and can be easily machined, may be used as a material of the transparent electrode 20.

Meanwhile, the transparent electrode 20 may be formed by being patterned in a mesh shape as shown in FIG. 1. The mesh shape generally means a shape in which a plurality of squared openings are uniformly arranged in a predetermined area. When the transparent electrode 20 is made of metal, the transparent electrode has excellent electric conductivity but reduces the transmittance of the touch panel (a ratio of transmitting light to incident light) due to an opaque metal color. The preferred embodiment of the present invention forms the transparent electrode 20 in a predetermined area in a mesh shape to make a size of a mesh pitch fine at several μm, such that an aperture ratio (a ratio of the opening area to the entire area) may reach 95% to 99.5%. Therefore, the transmittance of the touch panel may be improved by increasing the opening area of the transparent electrode 20 that make it easy to transmit light.

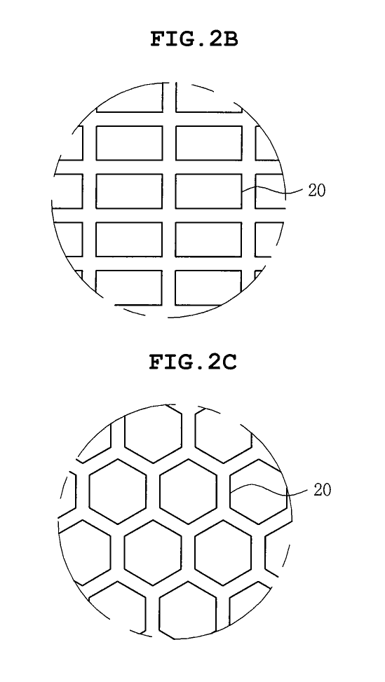

Herein, a pitch Pa of the mesh means a length of one side of a single squared opening and a line width Wa means a width of a single metal line patterned to surround the opening, as shown in FIG. 2A. The preferred embodiment of the present invention forms the transparent electrode 20 of metal, thereby increasing the transparency of the touch panel due to the transparent electrode 20 in the mesh shape while having the high electric conductivity of 150 Ω□ or less of sheet resistance.

The mesh shape is not limited the squared opening and therefore, may be an opening shape such as a rectangular shape (see FIG. 2B), a polygonal shape such as a hexagon (see FIG. 2C), or the like, an oval shape, a circular shape, or the like.

In this case, the line width Wa of the transparent electrode 20 may be 1 μm to 10 μm. The touch panel has excellent transmittance of 88% or more within the range.

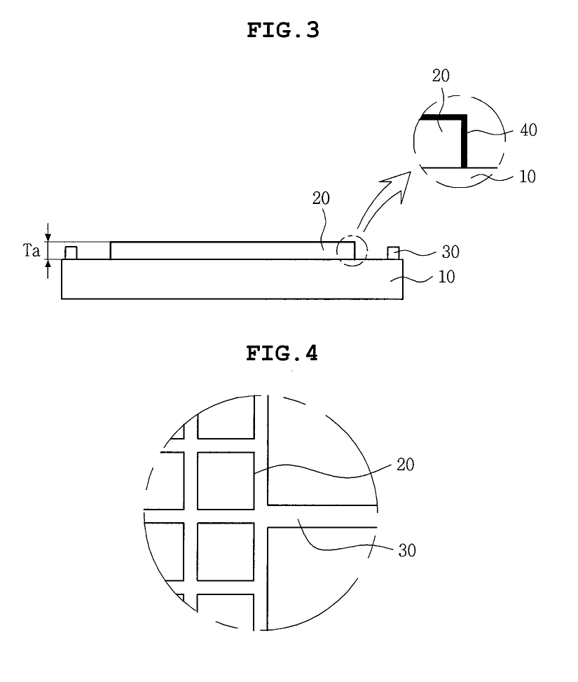

Further, as shown in FIG. 3, a thickness Ta of the transparent electrode 20 may be 0.01 μm to 2 μm. When the thickness Ta of the transparent electrode 20 is less than 0.01 μm, the electric conductivity may be reduced and when the thickness Ta exceeds 2 μm, the transmittance of the touch panel may be reduced.

Meanwhile, as shown in the enlarged view of FIG. 3, when the transparent electrode 20 is made of copper (Cu), the surface of the transparent electrode 20 may be subjected to a blackening process 40. In this case, the blackening process 40 precipitates Cu₂O or CuO by oxidizing the surface of the transparent electrode 20, wherein the Cu₂O is brown and thus, is referred to as a brown oxide and the CuO is black and thus, is referred to as black oxide. It is possible to prevent light from being reflected from the transparent electrode 20 by performing the blackening process 40 on the surface of the transparent electrode 20, thereby improving the visibility of the touch panel.

Next, the electrode wirings 30 are integrally formed on one end or both ends of the transparent electrode 20 by the extension of transparent electrode 20. In addition, the electrode wiring 30 extends so that one end thereof is connected to the transparent electrode 20 and the other end thereof is connected to the control unit (not shown). The electrode wiring 30 serves to receive electrical signals from the transparent electrode 20 and transmit the received electrical signals to the control unit. The electrode wiring 30 may be made of silver (Ag) as a material having high electric conductivity. However, the preferred embodiment of the present invention is not limited thereto and the electrode wiring 30 may be made of all the metals such as copper (Cu), gold (Au), aluminum (Al), or the like, all of which have excellent electric conductivity.

The preferred embodiment of the present invention is integrally formed with the transparent electrode 20, thereby simplifying the manufacturing process of the touch panel and reducing the manufacturing time. As shown in FIG. 4, the electrode wiring 30 made of the same metal as the transparent electrode 20 is formed to directly extend from the transparent electrode 20. When forming the transparent electrode 20 without a separate bonding process with the transparent electrode 20, the electrode wiring 30 is integrally formed with the transparent electrode 20, which may prevent step occurrence or bonding defects at the bonding portion. In addition, the degradation in transmittance due to the transparent electrode 20 of metal may be solved by increasing the aperture ratio by forming the transparent electrode in the mesh shape as described above.

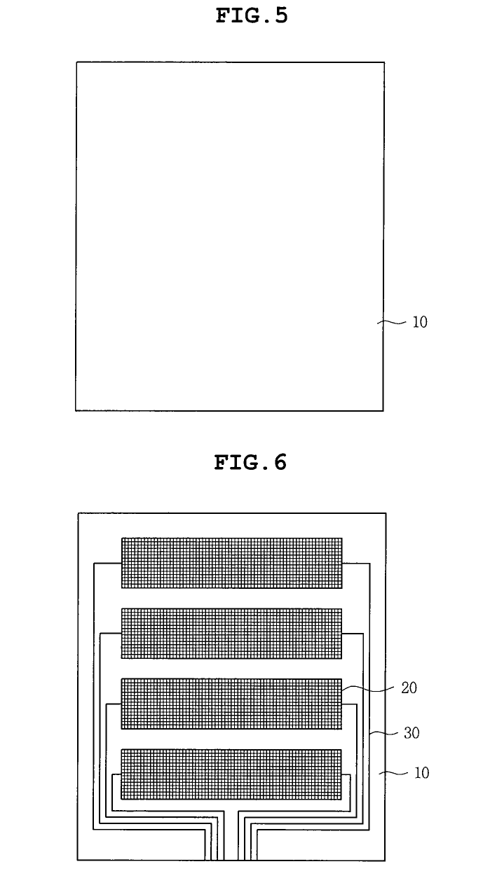

FIGS. 5 and 6 show the manufacturing process of the touch panel according to the preferred embodiment of the present invention. A method for manufacturing a touch panel according to the preferred embodiment of the present invention includes (A) providing the base member 10 and (B) integrally forming the transparent electrode 20 in the mesh shape including the plurality of openings and the electrode wirings 30 connected to one end or both ends of the transparent electrode 20 on the base member 10 by the metal patterning. Hereinafter, the method for manufacturing a touch panel according to the preferred embodiment of the present invention will be described with reference to FIGS. 5 and 6. The overlapping portion with the above-mentioned portions will be omitted or will be briefly described.

First, as shown in FIG. 5, the base member 10 is prepared. The base member 10 is made of a material having support force and transparency.

Next, as shown in FIG. 6, the transparent electrode 20 and the electrode wiring 30 connected to one end or both ends of the transparent electrode 20 are integrally formed on the base member 10 by the metal patterning. The preferred embodiment of the present invention forms the transparent electrode 20 and the electrode wiring 30 at one time by the same process, thereby reducing the manufacturing process time and preventing the bonding defects between the transparent electrode 20 and the electrode wiring 30.

The transparent electrode 20 and the electrode wiring 30 may be formed on the base member 10 by plating, sputtering, evaporation, or the like or may be formed by a printing process such as a silk screen method, a gravure printing method, or an inkjet printing method.

Meanwhile, when the transparent electrode 20 is made of copper (Cu), the surface of the transparent electrode 20 may be subjected to the blackening process 40 after the forming of the transparent electrode 20 and the electrode wiring 30 (see the enlarged view of FIG. 3). The blackening process 40 performs the heat treatment on the transparent electrode 20 at a temperature of 100° C. or more to oxidize the surface of the transparent electrode 20. It is possible to prevent light from being reflected from the transparent electrode 20 by performing the blackening process 40 on the surface of the transparent electrode 20.

As set forth above, the preferred embodiment of the present invention can simplify the process and reduce the process time for manufacturing the touch panel by integrally forming the electrode wirings on the transparent electrode made of metal. In addition, the preferred embodiment of the present invention can lower the opacity due to the metal color and increase the electric conductivity by forming the transparent electrode in a mesh shape and increasing the aperture ratio.

Although the preferred embodiments of the present invention have been disclosed for illustrative purposes, they are for specifically explaining the present invention and thus the touch panel and the method for manufacturing a touch panel according to the present invention are not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A touch panel, comprising:
a base member;
a transparent electrode formed on the base member in a mesh shape including a plurality of openings surrounded by a line patterned with metal; and
electrode wirings integrally formed on one end or both ends of the transparent electrode.

2. The touch panel as set forth in claim 1, wherein the metal is copper (Cu), aluminum (Al), gold (Au), or silver (Ag).

3. The touch panel as set forth in claim 1, wherein a width of the line patterned with the metal of the transparent electrode is 1 μm to 10 μm.

4. The touch panel as set forth in claim 1, wherein a thickness of the line patterned with the metal of the transparent electrode is 0.01 μm to 2 μm.

5. The touch panel as set forth in claim 1, wherein sheet resistance of the transparent electrode is 150 Ω/□ or less.

6. The touch panel as set forth in claim 1, wherein transmittance of the touch panel is 88% or more.

7. The touch panel as set forth in claim 1, wherein a surface of the transparent electrode is subjected to a black oxide treatment.

8. A method for manufacturing a touch panel, comprising:
(A) providing a base member; and
(B) integrally forming a transparent electrode in a mesh shape including a plurality of openings and electrode wirings connected to one end or both ends of the transparent electrode on the base member by metal patterning.

9. The method as set forth in claim 8, wherein the metal is copper (Cu), aluminum (Al), gold (Au), or silver (Ag).

10. The method as set forth in claim 8, wherein a width of the line patterned with the metal of the transparent electrode is 1 μm to 10 μm.

11. The method as set forth in claim 8, wherein a thickness of the line patterned with the metal of the transparent electrode is 0.01 μm to 2 μm.

12. The method as set forth in claim 8, wherein sheet resistance of the transparent electrode is 150 Ω/□ or less.

13. The method as set forth in claim 8, wherein transmittance of the touch panel is 88% or more.

14. The method as set forth in claim 8, further comprising performing a black oxide treatment on a surface of the transparent electrode after step (B).
